(19) United States
(12) Patent Application Publication
(10) Pub. No.: US 2013/0140552 A1
(43) Pub. Date: Jun. 6, 2013

(54) SEMICONDUCTOR DEVICE, METHOD FOR MANUFACTURING SAME, AND DISPLAY DEVICE

(71) Applicants: Hirohiko Nishiki, Osaka-shi (JP); Yoshimasa Chikama, Osaka-shi (JP); Tetsuya Aita, Osaka-shi (JP); Masahiko Suzuki, Osaka-shi (JP); Michiko Takei, Osaka-shi (JP); Okifumi Nakagawa, Osaka-shi (JP); Yoshiyuki Harumoto, Osaka-shi (JP); Yoshifumi Ohta, Osaka-shi (JP); Takeshi Hara, Osaka-shi (JP); Hinae Mizuno, Yamato-shi (JP)

(72) Inventors: Yuuji Mizuno, Osaka-shi (JP); Hirohiko Nishiki, Osaka-shi (JP); Yoshimasa Chikama, Osaka-shi (JP); Tetsuya Aita, Osaka-shi (JP); Masahiko Suzuki, Osaka-shi (JP); Michiko Takei, Osaka-shi (JP); Okifumi Nakagawa, Osaka-shi (JP); Yoshiyuki Harumoto, Osaka-shi (JP); Yoshifumi Ohta, Osaka-shi (JP); Takeshi Hara, Osaka-shi (JP)

(73) Assignee: SHARP KABUSHIKI KAISHA, Osaka-shi, Osaka (JP)

(21) Appl. No.: 13/581,007

(22) PCT Filed: Feb. 22, 2011
(86) PCT No.: PCT/JP2011/053761

§ 371 Date: Nov. 2, 2012

(30) Foreign Application Priority Data
Feb. 26, 2010 (JP) 2010-043486

(51) Int. Cl. H01L 29/786; H01L 29/66

(52) U.S. Cl. CPC H01L 29/786; H01L 29/66742
USPC 257/43; 438/104

(57) ABSTRACT

A semiconductor device (100) according to the present invention includes: an oxide semiconductor layer (31) formed on an insulating layer (21), the oxide semiconductor layer (31) containing at least one element selected from the group consisting of In, Zn, and Sn; first and second sacrificial layers (41a) and (41b) formed, with an interspace from each other, on the oxide semiconductor layer (31); a second electrode (52a) formed in contact with an upper face of the first sacrificial layer (41a) and an upper face of the oxide semiconductor layer (31); and a third electrode (52b) formed in contact with an upper face of the second sacrificial layer (41b) and an upper face of the oxide semiconductor layer (31). The first and second sacrificial layers (41a) and (41b) contain an oxide having at least one element selected from the group consisting of Zn, Ga, Mg, Ca, and Sr.

### TECHNICAL FIELD

The present invention relates to a semiconductor device having a thin film transistor (TFT) in which an oxide semiconductor is used, a method of producing the same, as well as a display device.

### BACKGROUND ART

In recent years, efforts are being made at developing TFTs in which an oxide semiconductor layer containing indium (In), zinc (Zn), gallium (Ga), or the like is used (for example, Patent Documents 1 to 3). A TFT in which an oxide semiconductor layer is used has high-mobility characteristics.

However, in a TFT having a bottom gate structure, during the etching steps for forming the source/drain electrodes, the underlying oxide semiconductor layer is liable to damage. Therefore, when an oxide semiconductor layer is used as a channel region of the TFT, among TFT characteristics, problems may occur in the gate voltage-drain current characteristics, e.g., a phenomenon where the drain current can no longer be controlled by a gate voltage, which results in a problem in that stable TFT characteristics are difficult to obtain.

On the other hand, for example, Patent Document 3 proposes forming on a channel region of an oxide semiconductor layer an insulating layer (hereinafter referred to as a protection layer) for protecting the channel region. This prevents the channel region of the oxide semiconductor layer from having a lowered resistance due to oxygen defects occurring in the etching steps for forming the source/drain electrodes, for example, thus realizing TFT characteristics with a small OFF current.

### CITATION LIST

### Patent Literature

[Patent Document 1] Japanese Laid-Open Patent Publication No. 2003-298062

[Patent Document 2] Japanese Laid-Open Patent Publication No. 2009-253204

[Patent Document 3] Japanese Laid-Open Patent Publication No. 2008-166716

### SUMMARY OF INVENTION

### Technical Problem

However, according to the TFT production method described in Patent Document 3, the protection layer is formed from silicon dioxide (SiO₂) or silicon nitride (SiNₓ) by a CVD (Chemical Vapor Deposition) or radio-frequency sputtering technique (RF-sputtering technique). Therefore, the throughput in forming the protection layer is small. Moreover, the need for a photomask in the formation of the protection layer induces an increased number of photomasks, thus resulting in a problem of increased production cost.

The present invention has been made in view of the above problems, and an objective thereof is to, in a TFT in which an oxide semiconductor layer is used, stably realize good TFT characteristics while preventing increases in the number of production steps and in the production cost.

### Solution to Problem

A semiconductor device according to the present invention includes: an insulative substrate; a first electrode formed on the insulative substrate; an insulating layer formed on the first electrode; an oxide semiconductor layer formed on the insulating layer, the oxide semiconductor layer containing at least one element selected from the group consisting of In, Zn, and Sn; first and second sacrificial layers formed, with an interspace from each other, on the oxide semiconductor layer; a second electrode formed in contact with an upper face of the first sacrificial layer and an upper face of the oxide semiconductor layer; and a third electrode formed in contact with an upper face of the second sacrificial layer and the upper face of the oxide semiconductor layer, wherein the first and second sacrificial layers contain an oxide having at least one element selected from the group consisting of Zn, Ga, Mg, Ca, and Sr.

In one embodiment, wherein the oxide semiconductor layer is an amorphous oxide layer containing In, Zn, and Ga.

In one embodiment, the first and second sacrificial layers contain zinc oxide.

In one embodiment, the first and second sacrificial layers contain an alkaline-earth metal, a transition metal, an earth metal such as Al, a VB group element such as Sb or Bi, or an IVB group element such as Ge, Sn, or Pb.

In one embodiment, the first and second sacrificial layers are electrically conductive layers.

In one embodiment, the first and second sacrificial layers are semiconductor layers.

A display device according to the present invention includes the above semiconductor device.

A method of producing a semiconductor device according to the present invention includes: step a of providing an insulative substrate having a first electrode and an insulating layer formed on the first electrode; step b of forming on the insulating layer an oxide semiconductor layer containing at least one element selected from the group consisting of In, Zn, and Sn; step c of forming a sacrificial layer covering at least a portion of the oxide semiconductor layer to become a channel region, the sacrificial layer containing an oxide having at least one element selected from the group consisting of Zn, Ga, Mg, Ca, and Sr; step d of forming an electrically conductive film on the sacrificial layer; step e of forming a source electrode and a drain electrode by patterning the electrically conductive film; and step f of a first sacrificial layer connected to the source electrode and a second sacrificial layer connected to the drain electrode by removing a portion of the sacrificial layer that is not covered by the source electrode and the drain electrode.

In one embodiment, steps b and c include: a step of forming an oxide semiconductor film on the insulating layer; a step of forming an oxide film on the oxide semiconductor film; and step z1 of forming the oxide semiconductor layer from the oxide semiconductor film and forming the sacrificial layer from the oxide film, by wet etching the oxide semiconductor film and the oxide film by using an acid-type etchant such that the oxide film has an etching rate which is greater than an etching rate of the oxide semiconductor film.

In one embodiment, step z1 includes step z2 of conducting a wet etching by using an acid-type etchant such that the oxide film has an etching rate which is no less than 3 times and no more than 20 times the etching rate of the oxide semiconductor film.

In one embodiment, steps b and c include a step of forming an oxide semiconductor film on the insulating layer; a step of forming an oxide film on the oxide semiconductor film; and step y1 of forming the oxide semiconductor layer from the oxide semiconductor film and forming the sacrificial layer from the oxide film, by dry etching the oxide semiconductor film and the oxide film.

In one embodiment, step f includes step f1 of wet etching the sacrificial layer by using an acid-type etchant such that the sacrificial layer has an etching rate which is greater than an etching rate of the oxide semiconductor layer.

In one embodiment, step fl includes step f2 of conducting a wet etching by using an acid-type etchant such that the sacrificial layer has an etching rate which is 60 times or more of the etching rate of the oxide semiconductor layer.

In one embodiment, step f includes step f3 of conducting a wet etching by using an alkaline-type etchant.

### Advantageous Effects of Invention

According to the present invention, in a TFT in which an oxide semiconductor layer is used, good TFT characteristics are stably realize while preventing increases in the number of production steps and in the production cost.

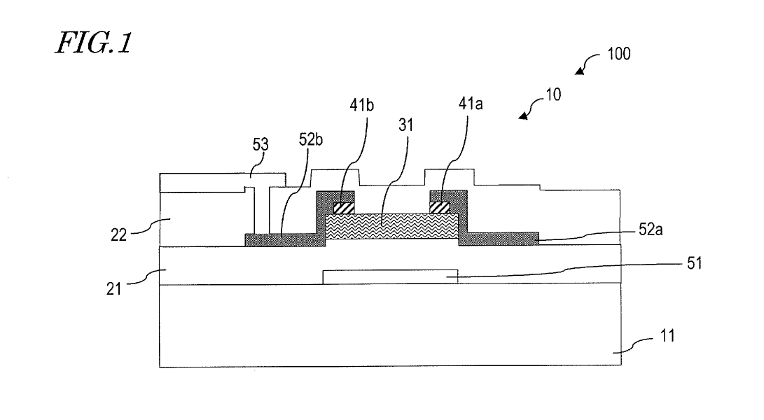

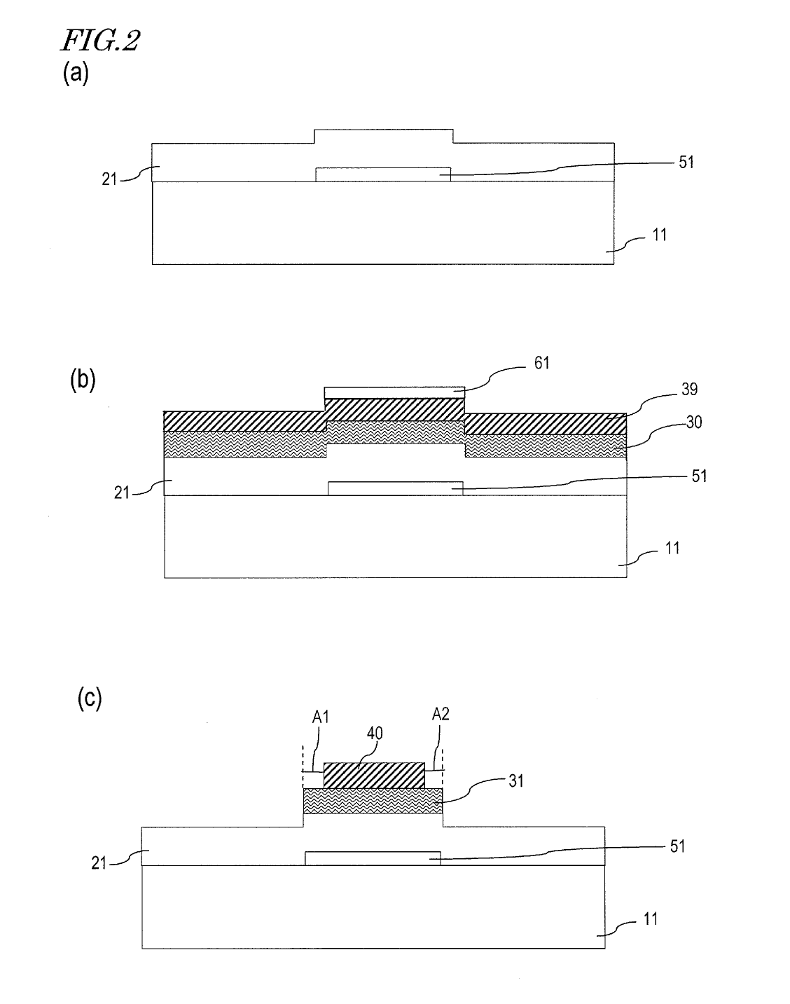

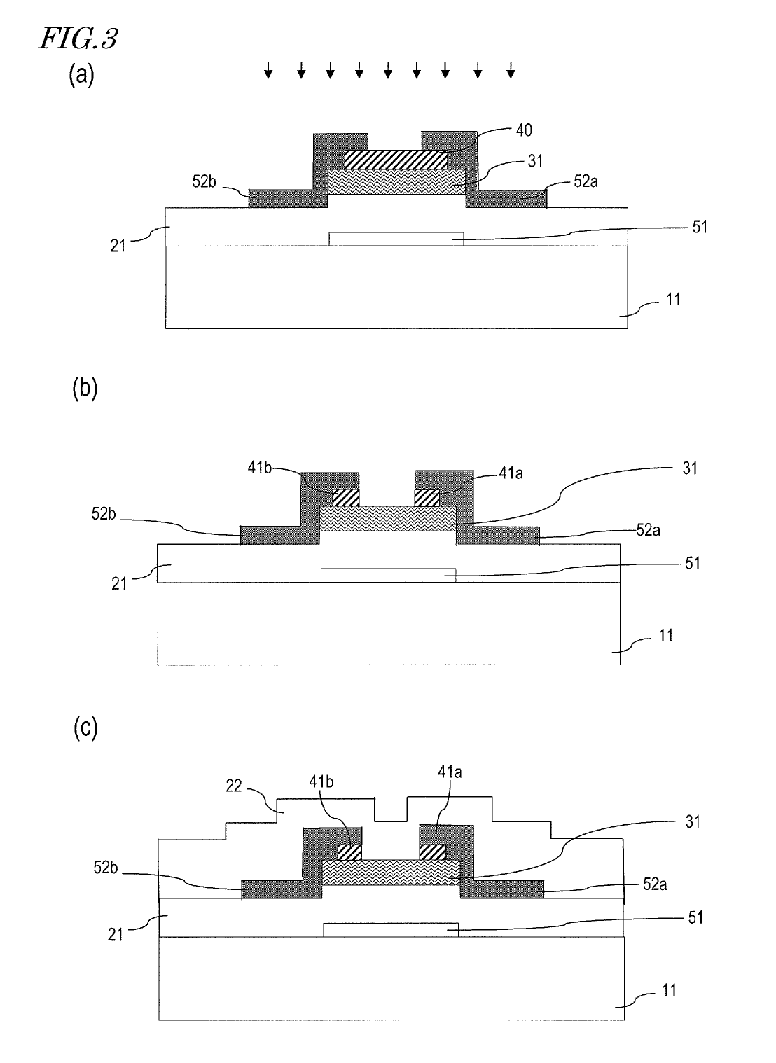

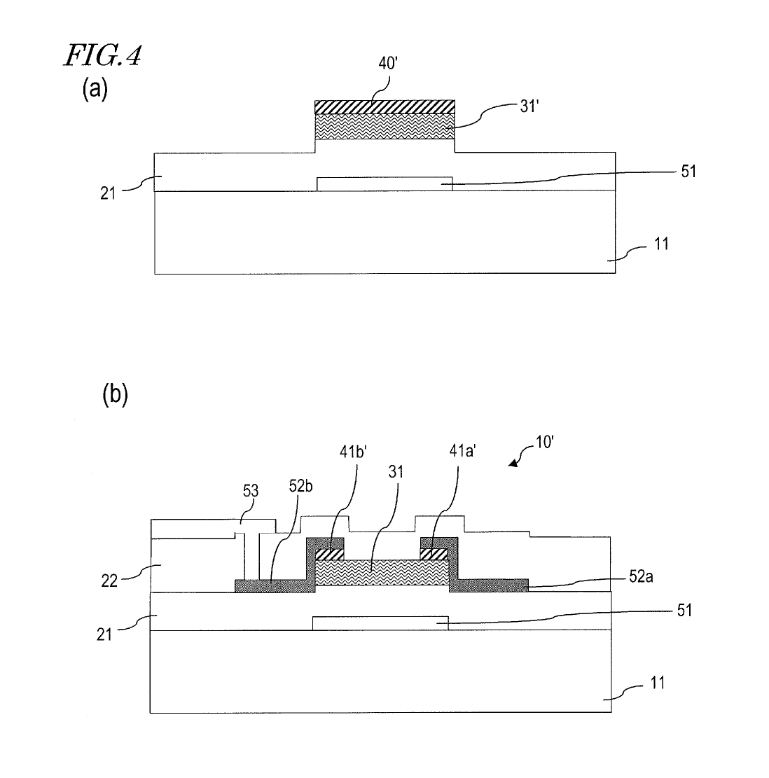

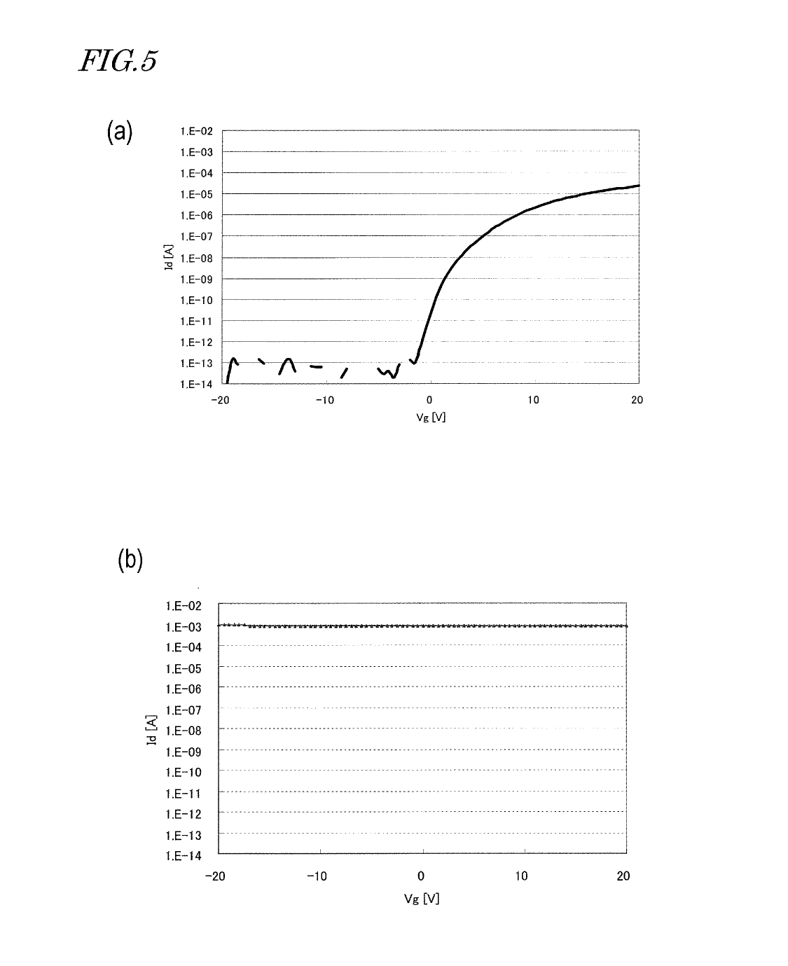

### BRIEF DESCRIPTION OF DRAWINGS

[FIG. 1] A schematic cross-sectional view of a semiconductor device 100 according to an embodiment of the present invention. [FIG. 2] (a) to (c) are diagrams describing production steps for the semiconductor device 100.

[FIG. 3] (a) to (c) are diagrams describing production steps for the semiconductor device 100.

[FIG. 4] (a) and (b) are diagrams describing other production steps for the semiconductor device 100.

[FIG. 5] (a) is a graph showing the gate voltage-drain current characteristics of a TFT 10, and (b) is a graph showing the gate voltage-drain current characteristics of a TFT which has been produced without forming an island-like sacrificial layer 40.

### DESCRIPTION OF EMBODIMENTS

With reference to the drawings, a semiconductor device according to an embodiment of the present invention and a method of producing the same will be described. However, the present invention is not limited to the illustrated embodiment.

FIG. 1 is a schematic cross-sectional view of a semiconductor device 100 according to an embodiment of the present invention.

As shown in FIG. 1, the semiconductor device 100 includes a TFT 10 on an insulative substrate (e.g., a glass substrate) 11. The TFT 10 includes a first electrode (gate electrode) 51, a first insulating layer (gate insulating layer) 21 formed on the first electrode 51, and an oxide semiconductor layer 31 formed on the first insulating layer 21. The TFT 10 has first and second sacrificial layers 41a and 41b which are formed on the oxide semiconductor layer 31 with an interspace from each other. Furthermore, the TFT 10 has a second electrode (source electrode) 52a which is formed in contact with an upper face of the first sacrificial layer 41a and an upper face of the oxide semiconductor layer 31, and a third electrode (drain electrode) 52b which is formed in contact with an upper face of the second sacrificial layer 41b and the upper face of the oxide semiconductor layer 31. Furthermore, the TFT 10 has a second insulating layer 22 over the second electrode 52a and the third electrode 52, and a pixel electrode 53 connected to the third electrode 52b.

The first insulating layer 21 is made of silicon dioxide (SiO₂) or silicon nitride (SiNₓ), or a multilayer structure thereof, for example.

The oxide semiconductor layer 31 contains at least one element selected from the group consisting of In, Zn, and Sn (tin). The oxide semiconductor layer 31 is an amorphous metal oxide semiconductor layer (a-IGZO layer) containing the elements of In, Ga, and Zn, for example.

The first sacrificial layer 41a and the second sacrificial layer 41b (which may be collectively referred to as a “sacrificial layer 41”) contain an oxide including at least one element selected from the group consisting of Zn,

Ga, Mg (magnesium), Ca (calcium), and Sr (strontium). The sacrificial layer 41 contains zinc oxide (ZnO), for example. Other than zinc oxide (ZnO), the sacrificial layer 41 may be composed of gallium oxide (Ga₂O₃), magnesium oxide (MgO), calcium oxide (CaO), strontium oxide (SrO), or what is obtained by doping these with an alkaline-earth metal, a transition metal, an earth metal such as Al, a VB group element such as Sb or Bi, or an IVB group element such as Ge, Sn, or Pb, for example. Since the sacrificial layer 41 is separated into a source-electrode side and a drain-electrode side, it may be an electrically conductive layer, an insulating layer, or a semiconductor layer.

The first, second, and third electrodes 51, 52a, and 52b have a multilayer structure of Ti (titanium)/Al (aluminum)/Ti, Al/Ti, or Cu (copper)/Ti, for example. The second insulating layer 22 is silicon dioxide or silicon nitride, for example. The pixel electrode 53 is a transparent electrode of ITO (Indium Tin Oxide), for example.

The semiconductor device 100 is used for display devices such as liquid crystal display devices or organic EL (Electro Luminescence) display devices.

Next, with reference to FIG. 2 and FIG. 3, a method of producing the TFT 10 will be specifically described.

As shown in FIG. 2(a), a first electrode (gate electrode) 51 is formed on an insulative substrate (e.g., glass substrate) 11. The first electrode (gate electrode) 51 has a multilayer structure of Ti (titanium)/Al (aluminum)/Ti, Al/Ti, or Cu (copper)/Ti, for example. The first electrode 51 has a thickness of e.g. 200 nm to 600 nm.

As shown in FIG. 2(b), a first insulating layer (gate insulating layer) 21 is formed on the first electrode 51. The first insulating layer 21 may be made of silicon dioxide or silicon nitride, for example. The first insulating layer 21 has a thickness of e.g. 10 nm to 500 nm.

Next, an oxide semiconductor film (e.g. a-IGZO film) 30 and an oxide film (e.g. zinc oxide film) 39 are formed by a DC sputtering technique (direct-current sputtering technique), and a photoresist 61 is formed by photolithography. The oxide semiconductor film 30 has a thickness of e.g. 10 nm to 100 nm. The thickness of the oxide film 39 is preferably no less than 20 nm and no more than 100 nm, for example, and more preferably no less than 40 nm and no more than 70 nm, because the crystal of the oxide film 39 can cover the underlying oxide semiconductor while leaving no gap when it is 40 nm or more, and also from the standpoint of producibility. If the photoresist 61 is formed via backside exposure, the production cost can be reduced because a photomask is not used.

Thereafter, the oxide semiconductor film 30 and the oxide film 39 are patterned. The patterning is performed via wet etching or dry etching.

A method of patterning the oxide semiconductor film 30 and the oxide film 39 via wet etching will be described.

As shown in FIG. 2(c), an oxide semiconductor layer 31 and an island-like sacrificial layer 40 are formed by wet etching using an acid-type etchant E1. Because of a difference in different selection ratio, the island-like sacrificial layer 40 is shaped as if pressed inward of the oxide semiconductor layer 31. In other words, as viewed from above the substrate, the island-like sacrificial layer 40 is located inside of the oxide semiconductor layer 31. On the surface of the oxide semiconductor layer 31, a region A1 in which a second electrode (source electrode) 52a and the oxide semiconductor layer 31 come in contact, and a region A2 in which a third electrode (drain electrode) 52b and the oxide semiconductor layer 31 come in contact, described later, are formed. The acid-type etchant E1 is preferably an acid-type etchant such that the oxide film 39 has an etching rate which is greater than the etching rate of the oxide semiconductor film 30, and more preferably such that the oxide film 39 has an etching rate which is no less than 3 times and no more than 20 times the etching rate of the oxide semiconductor film 30. Use of an etchant such that the oxide film 39 has an etching rate which is no less than 3 times and no more than 20 times the etching rate of the oxide semiconductor film 30 allows regions A1 and A2 having sufficient areas to be obtained with greater certainty. The distance of the regions A1 and A2 may be no less than 5 μm and no more than 15 μm. This can be realized by prescribing an appropriate overlap between the second electrode (source electrode) 52a and the oxide semiconductor layer 31. Specifically, the acid-type etchant E1 may be, for example, a 5% (volumetric concentration)-or-less aqueous solution of a mixed acid whose main component is phosphoric acid (H₃PO₄) (e.g., an acid containing phosphoric acid (H₃PO₄), acetic acid (CH₃COOH), and nitric acid (HNO₃)) described later, a 5% (volumetric concentration) aqueous solution of oxalic acid ((COOH)₂), an aqueous solution of acetic acid or an aqueous solution of hydrochloric acid (HCl).

Thereafter, the photoresist 61 is removed.

Next, as shown in FIG. 3(a), an electrically conductive film (not shown) is formed on the island-like sacrificial layer 40. Then, the electrically conductive film is patterned by dry etching, for example, thus forming a second electrode 52a and a third electrode 52b. At this time, damage to the oxide semiconductor layer 31 caused by dry etching can be prevented by the island-like sacrificial layer 40, thus preventing the channel region of the oxide semiconductor layer 31 from having a lowered resistance.

Next, as shown in FIG. 3(b), with an acid-type etchant E2 or an alkaline-type etchant E3, the portion of the island-like sacrificial layer 40 that is not covered by the second electrode 52a and the third electrode 52b is removed by wet etching, thereby forming a first sacrificial layer 41a and a second sacrificial layer 41b. As a result, the first sacrificial layer 41a and the second sacrificial layer 41b become separated, and also a portion of the oxide semiconductor layer 31 that is located between the first sacrificial layer 41a and the second sacrificial layer 41b is exposed.

As the acid-type etchant E2, an acid-type etchant such that the island-like sacrificial layer (sacrificial layer 41) 40 has an etching rate which is greater than the etching rate of the oxide semiconductor layer 31 is preferable, and an acid-type etchant such that the island-like sacrificial layer 40 has an etching rate which is 60 times or more of the etching rate of the oxide semiconductor layer 31 is more preferable. Use of an acid-type etchant such that the island-like sacrificial layer 40 has an etching rate which is 60 times or more of the etching rate of the oxide semiconductor layer 31 makes it possible to form the first sacrificial layer 41a and the second sacrificial layer 41b through etching the island-like sacrificial layer 40, while also minimizing concurrent etching of the oxide semiconductor layer 31. Therefore, the larger the difference in etching rate is, the more preferable it is. There is no particular upper limit value, which may be appropriately determined by taking the etching treatment time and the like into consideration. Specifically, the acid-type etchant E2 may be a 0.2% (volumetric concentration) aqueous solution of nitric acid (HNO₃) described later, for example. When the acid-type etchant E2 is used, a part of the oxide semiconductor layer 31 may also become somewhat etched, and therefore the etching treatment time is controlled so that the oxide semiconductor layer 31 is left with a sufficient thickness. As the alkaline-type etchant E3, for example, ammonia (NH₃) and an aqueous solution of ammonia, an aqueous solution of 2-aminoethanol, a 2.38% (volumetric ratio) aqueous solution of tetramethylammonium hydroxide (TMAH), an aqueous solution of sodium hydroxide (NaOH) or an aqueous solution of potassium hydroxide (KOH) is preferable. The island-like sacrificial layer 40 (sacrificial layer 41) dissolves in the alkaline-type etchant E3, but the oxide semiconductor layer 31 hardly dissolves in the alkaline-type etchant E3.

Next, as shown in FIG. 3(c), a second insulating layer (passivation layer) 22 is formed by a known method. Thereafter, a contact hole leading to the drain electrode 52b is formed by a known method. Thereafter, a pixel electrode 53 is formed of a transparent electrode, e.g., ITO, as shown in FIG. 1 by a known method. The second insulating layer 22 may be formed by an inorganic material of silicon dioxide or silicon nitride, or an organic material of acrylic resin, or a combination thereof, for example. The second insulating layer 22 has a thickness of 600 nm to 1000 nm, for example. The pixel electrode 53 has a thickness of 50 nm to 200 nm, for example.

Although the patterning of the oxide semiconductor film 30 and the oxide film 39 is achieved via wet etching in the above method, it may alternatively be achieved via dry etching. FIGS. 4(a) and (b) are schematic cross-sectional views for describing production steps in the case where patterning of the oxide semiconductor film 30 and the oxide film 39 is conducted via dry etching. For simplicity, those constituent elements having similar counterparts in FIG. 2 and FIG. 3 are denoted by like reference numerals, and overlapping descriptions are avoided.

As described above, after the oxide semiconductor film 30, the oxide film 39, and a photoresist 61 shown in FIG. 2(b) are formed, with reference to FIG. 4(a), the oxide semiconductor film 30 and the oxide film 39 are simultaneously dry-etched, whereby the oxide semiconductor layer 31 and an island-like sacrificial layer 40′ are obtained. For the dry etching, for example, argon (Ar) and methane (CH₄) , argon and carbon tetrafluoride (CF₄), or carbon tetrafluoride and oxygen (O₂) can be used. Unlike in the aforementioned wet etching treatment, the island-like sacrificial layer 40′ has substantially the same planar shape as that of the oxide semiconductor layer 31. Note that, even when conducting dry etching, an island-like sacrificial layer whose planar shape is one-size smaller than the oxide semiconductor layer 31 as shown in FIG. 2(c) can also be formed depending on the shape of the photoresist 61. Thereafter, the photoresist 61 is removed.

Next, through the above-described production steps, a TFT 10′ as shown in FIG. 4(b) is obtained. The TFT 10′ has a first sacrificial layer 41a′ and a second sacrificial layer 41b′ which are formed with an interspace from each other on the oxide semiconductor layer 31. Unlike the TFT 10, the TFT 10′ is structured so as to be connected to the second electrode (source electrode) 52a and the third electrode (drain electrode) 52b at the side faces of the oxide semiconductor layer 31.

The first sacrificial layer 41a′ and the second sacrificial layer 41b′ (which may collectively be referred to as a “sacrificial layer 41′”) are formed of the same material as that of the sacrificial layer 41 above.

Particularly in the case where the sacrificial layer 41 is an insulating layer or a semiconductor layer, the TFT 10 is more preferable than the TFT 10′ because the TFT comes in contact with the second electrode (source electrode) 52a and the third electrode (drain electrode) 52b not only at the side faces of the oxide semiconductor layer 31 but also in the regions A1 and A2.

The sacrificial layer 41 (41′) is made of zinc oxide, for example. Since zinc oxide is an amphoteric oxide and easily dissolves in acids and alkalis, it can be treated by wet etching. Zinc oxide can be formed by a DC sputtering technique, as are amorphous oxides, and provides a large deposition rate. Thus, film formation can be conducted without employing a CVD technique or an RF-sputtering technique, so that continuous film formation of the oxide semiconductor film 30 and the oxide film 39 is possible, whereby a greater throughput is provided than in the case of forming the sacrificial layer 41 (41′) from silicon dioxide, for example. Other than zinc oxide, the aforementioned gallium oxide, magnesium oxide, calcium oxide, strontium oxide, or what is obtained by doping these with an alkaline-earth metal, a transition metal, an earth metal such as A1, a VB group element such as Sb or Bi, or an IVB group element such as Ge, Sn, or Pb, for example, can also be similarly formed by a DC sputtering technique. The oxide semiconductor layer 31 and the island-like sacrificial layer 40 (40′) may be formed in a region where a source bus line and a gate bus line (not shown) of the semiconductor device intersect.

Next, the etchants E1 to E3 to be used in the above method will be described.

The inventors have studied the etching rates of the oxide semiconductor layer 31 and the island-like sacrificial layer 40 (40′) with respect to the respective etchants E1 to E3.

The material of the oxide semiconductor layer 31 was a-IGZO, and the material of the sacrificial layer 41 (41′) was zinc oxide.

In the case where a wet etching treatment was conducted by using e.g. a 5% (volumetric concentration) aqueous solution of oxalic acid ((COOH)₂) as the acid-type etchant E1, the solution having a temperature of 25° C., the oxide semiconductor layer 31 had an etching rate of 60 nm/min. On the other hand, the sacrificial layer 41 (41′) had an etching rate of 300 nm/min. Therefore, the etching rate of the sacrificial layer 41 (41′) was five times the etching rate of the oxide semiconductor layer 31. Similarly, in the case where a wet etching treatment was conducted by using e.g. a 5% (volumetric concentration)-or-less aqueous solution of a mixed acid whose main component is phosphoric acid (H₃PO₄) (e.g., an acid containing phosphoric acid (H₃PO₄), acetic acid (CH₃COOH), and nitric acid (HNO₃)), the solution having a temperature of 25° C., the oxide semiconductor layer 31 had an etching rate of 75 nm/min. On the other hand, the sacrificial layer 41 (41′) had an etching rate of 500 nm/min. Therefore, the etching rate of the sacrificial layer 41 (41′) is 6.66 times the etching rate of the oxide semiconductor layer 31.

In the case where a wet etching treatment was conducted by using e.g. a 0.5% (volumetric concentration) aqueous solution of nitric acid (HNO₃) as the acid-type etchant E2, the solution having a temperature of 25° C., the oxide semiconductor layer 31 had an etching rate of 5 nm/min. On the other hand, the sacrificial layer 41 (41′) had an etching rate of 300 nm/min. Therefore, the etching rate of the sacrificial layer 41 (41′) is 60 times the etching rate of the oxide semiconductor layer 31.

In the case where e.g. a 2.38% (volumetric ratio) aqueous solution of tetramethylammonium hydroxide (TMAH) was used as the alkaline-type etchant E3, the oxide semiconductor layer 31 did not dissolve. On the other hand, the sacrificial layer 41 (41′) had an etching rate of 5 nm/min or less.

Thus it has been confirmed that the etchants E1 to E3 are suitable for use.

Next, the TFT characteristics of the TFT 10 (or TFT 10′) will be described.

FIG. 5(a) is a graph showing the gate voltage-drain current characteristics of the TFT 10 (or TFT 10′), and FIG. 5(b) is a graph showing the gate voltage-drain current characteristics of a TFT which is manufactured without forming the island-like sacrificial layer 40 (40′).

As shown in FIG. 5(a), the TFT 10 (or TFT 10′) has good ON/OFF characteristics, such that the threshold voltage (Vth) is controlled within a desired range.

As described above, the second electrode 52a and the third electrode 52b are formed by dry etching using a halogen gas such as fluorine or chlorine. Therefore, in the case where the island-like sacrificial layer 40 is not formed, a part of the oxide semiconductor layer 31 is exposed in the dry etching gas. At this time, the channel region of the oxide semiconductor layer 31 is also damaged so that the TFT characteristics are deteriorated (FIG. 5(b)). This is considered to be because, since the channel region of the oxide semiconductor layer 31 is exposed in the halogen gas having a plasma state, oxygen, for example, separates from the amorphous metal oxide contained in the oxide semiconductor layer 31, thus resulting in a large OFF current due to lowering of the channel region resistance.

The island-like sacrificial layer 40 is formed at least on the channel region of the oxide semiconductor layer 31, In this state, a dry etching for forming the second electrode 52a and the third electrode 52b is performed. As a result, the channel region is prevented from being directly exposed to the etching ambient (e.g., plasma species, fast neutrons, or secondary electrons), thus preventing occurrence of excess carriers in the channel region, whereby good transistor characteristics can be obtained.

### INDUSTRIAL APPLICABILITY

The present invention has a very broad range of applications, and is applicable to semiconductor devices having TFTs, or electronic devices of various fields that have such semiconductor devices. For example, it can be used in active-matrix type liquid crystal display devices or organic EL display devices. Such display devices are applicable as display screens of mobile phones or portable game machines, monitors of digital cameras, and so on, for example. Therefore, the present invention is applicable to any and all electronic devices in which a liquid crystal display device or an organic EL display device is incorporated.

### REFERENCE SIGNS LIST

10 TFT
11 insulative substrate
21, 22 insulating layer
31 oxide semiconductor layer
41, 41a, 41b, 41′, 41a′, 41b′ sacrificial layer
51 gate electrode
52a source electrode
52b drain electrode
53 pixel electrode
100 semiconductor device

1. A semiconductor device comprising:
an insulative substrate;
a first electrode formed on the insulative substrate;
an insulating layer formed on the first electrode;
an oxide semiconductor layer formed on the insulating layer, the oxide semiconductor layer containing at least one element selected from the group consisting of In, Zn, and Sn;
first and second sacrificial layers formed, with an interspace from each other, on the oxide semiconductor layer;
a second electrode formed in contact with an upper face of the first sacrificial layer and an upper face of the oxide semiconductor layer; and
a third electrode formed in contact with an upper face of the second sacrificial layer and the upper face of the oxide semiconductor layer, wherein
the first and second sacrificial layers contain an oxide having at least one element selected from the group consisting of Zn, Ga, Mg, Ca, and Sr.

2. The semiconductor device of claim 1, wherein the oxide semiconductor layer is an amorphous oxide layer containing In, Zn, and Ga.

3. The semiconductor device of claim 1, wherein the first and second sacrificial layers contain zinc oxide.

4. The semiconductor device of claim 1, wherein the first and second sacrificial layers contain an alkaline-earth metal, a transition metal, an earth metal, a VB group element, or an IVB group element.

5. The semiconductor device of claim 1, wherein the first and second sacrificial layers are electrically conductive layers.

6. The semiconductor device of claim 1, wherein the first and second sacrificial layers are semiconductor layers.

7. A display device comprising the semiconductor device of claim 1.

8. A method of producing a semiconductor device, comprising:
step a of providing an insulative substrate having a first electrode and an insulating layer formed on the first electrode;
step b of forming on the insulating layer an oxide semiconductor layer containing at least one element selected from the group consisting of In, Zn, and Sn;
step c of forming a sacrificial layer covering at least a portion of the oxide semiconductor layer to become a channel region, the sacrificial layer containing an oxide having at least one element selected from the group consisting of Zn, Ga, Mg, Ca, and Sr;
step d of forming an electrically conductive film on the sacrificial layer;
step e of forming a source electrode and a drain electrode by patterning the electrically conductive film; and
step f of a first sacrificial layer connected to the source electrode and a second sacrificial layer connected to the drain electrode by removing a portion of the sacrificial layer that is not covered by the source electrode and the drain electrode.

9. The method of producing a semiconductor device of claim 8, wherein,
steps b and c comprise:
a step of forming an oxide semiconductor film on the insulating layer;
a step of forming an oxide film on the oxide semiconductor film; and
step z1 of forming the oxide semiconductor layer from the oxide semiconductor film and forming the sacrificial layer from the oxide film, by wet etching the oxide semiconductor film and the oxide film by using an acid-type etchant such that the oxide film has an etching rate which is greater than an etching rate of the oxide semiconductor film.

10. The method of producing a semiconductor device of claim 9, wherein step z1 comprises step z2 of conducting a wet etching by using an acid-type etchant such that the oxide film has an etching rate which is no less than 3 times and no more than 20 times the etching rate of the oxide semiconductor film.

11. The method of producing a semiconductor device of claim 8, wherein,
steps b and c comprise a step of forming an oxide semiconductor film on the insulating layer;
a step of forming an oxide film on the oxide semiconductor film; and
step y1 of forming the oxide semiconductor layer from the oxide semiconductor film and forming the sacrificial layer from the oxide film, by dry etching the oxide semiconductor film and the oxide film.

12. The method of producing a semiconductor device of claim 8, wherein step f comprises step f1 of wet etching the sacrificial layer by using an acid-type etchant such that the sacrificial layer has an etching rate which is greater than an etching rate of the oxide semiconductor layer.

13. The method of producing a semiconductor device of claim 12, wherein step f1 comprises step f2 of conducting a wet etching by using an acid-type etchant such that the sacrificial layer has an etching rate which is 60 times or more of the etching rate of the oxide semiconductor layer.

14. The method of producing a semiconductor device of claim 8, wherein step f comprises step f3 of conducting a wet etching by using an alkaline-type etchant.
